(19) United States
(12) Patent Application Publication
(10) Pub. No.: US 2025/0385219 A1
(43) Pub. Date: Dec. 18, 2025

(54) Method of Electronic Devices Packaging Underfill

(71) Applicant: Enjet Co. LTD., Suwon-si (KR)

(72) Inventors: Do Young Byun, Seoul (KR); Baek Hoon Seong, Hwaseong-si (KR); Hyungdong Lee, Hwaseong-si (KR)

(21) Appl. No.: 18/914,983

(22) Filed: Oct. 14, 2024

(30) Foreign Application Priority Data
Jun. 18, 2024 (KR) 10-2024-0078803

(51) Int. Cl. H01L 23/00

(52) U.S. Cl. CPC H01L 24/83; H01L 24/27; H01L 2224/2731; H01L 2224/83009; H01L 2224/83102; H01L 2924/381

(57) ABSTRACT

The present disclosure relates to a method of electronic devices packaging underfill, the method of electronic devices packaging underfill according to the present disclosure includes a step of loading a substrate, where an electronic device is stacked, on a stage; a step of transferring heat so that the substrate maintains a constant temperature; a step of transferring heat so that a dispenser that discharges a filler maintains a constant temperature; a step of applying a liquid filler for underfilling to a side surface of the electronic device using the dispenser; and a step of discharging a gas towards the filler applied to the side surface of the electronic device using a gas discharger in order to pressurize the filler in a capillary flow direction.

### 1. FIELD

The present disclosure relates to a method of electronic devices packaging underfill, and more particularly, to a method of electronic devices packaging underfill that can improve the penetration force of a filler for underfilling, thereby minimizing void creation, and that can shorten underfill filling time.

### 2. BACKGROUND

As miniaturization of semiconductor devices reaches its limit, packaging technology is becoming important. Packaging technology plays the role of protecting, electrically connecting, and mechanically fixing elements such as semiconductors, resistors, and capacitors in electronic devices, and discharging heat efficiently. Recently, multiple chip packages such as Multi-Chip Package (MCP) and System in Package (SiP), which integrate multiple chips through 3D stacking technology, have emerged, contributing to the lightweightness and miniaturization of mobile devices and wearable devices.

Underfilling, which is one of the packaging technologies, plays an important role in various package types such as Flip-Chip, Ball Grid Array (BGA), and CSP (Chip Scale Package). Underfilling prevents device damage from physical and chemical shock and temperature changes, prevents electrical migration, and delays problems caused by dust and moisture. Underfilling is divided into methods of filling after bonding (CUF, MUF) and methods of applying in advance before bonding. Capillary Underfill (CUF) uses capillary flow to fill a gap between a chip and a substrate, and Molded Underfill (MUF) simplifies the process by performing an underfilling function together during a molding process.

In the CUF method, fluid flow analysis is used, and a filling speed of an underfill material is determined based on its surface tension and viscosity. However, in actual processes, non-Newtonian fluids can be used, and problems may arise due to resistance of bumps. Incomplete filling creates voids to cause defects between the semiconductor device and the substrate, which can cause the defective phenomenon of bumps falling off due to heat during device operation. If a filler is excessively applied to prevent this, the top surface of the device may be contaminated due to overflow, which may result in the inability to stack semiconductor devices.

In order to solve this conventional problem, a prior art patent (Korean Patent Registration No. 10-2047025) proposed an underfill method and apparatus, where a filler is charged according to the principle of electrowetting, and then applied between a substrate and a microelectronic device, and then an electric field is applied, so that the wettability of the filler is controlled by the electric force acting on the filler, thereby improving the filling efficiency. In other words, when an electric charge exists on a surface of the liquid, and an electric field exists around the liquid, the wettability (surface tension) of the liquid can be controlled by the electric force acting on the liquid.

According to this method of the prior art patent, an effect of enhancement of penetration speed by lowering the surface tension of the filler can be observed, but controllable variables in an actual underfill process are more complex and can generate various difficulties depending on the package type of the device. In particular, efforts to increase the electrical signal density are accelerating, in a situation where heterogeneous integration is emerging, that includes Chiplet technology, in which the size of bump is becoming more refined (the bump integration has gradually become more dense in the form of a micro bump, from 102 Counts/mm² of flip chips to 5×102 Counts/mm² of 2.5D/3D ICs, and 104 Counts/mm² of SolC). Accordingly, a pitch of the bump is also reduced at the same time, and thus there is a continuous need to improve the efficiency of the underfill process.

### PRIOR ART LITERATURE

### Patent Document

Korean Patent Registration No. 10-2047025

### SUMMARY

Therefore, a purpose of the present disclosure is to solve the problems of prior art mentioned above, that is, to provide a method of electronic devices packaging underfill, that can improve the penetration force of the underfill filler to minimize void creation and shorten the underfill filling time.

The above-mentioned purpose is achieved, according to the present disclosure by a method of electronic devices packaging underfill; the method including a step of loading a substrate, where an electronic device is stacked, on a stage; a step of transferring heat so that the substrate maintains a constant temperature; a step of transferring heat so that a dispenser for discharging a filler maintains a constant temperature; a step of applying a liquid filler for underfilling to a side surface of the electronic device using the dispenser; and a step of discharging a gas towards the filler applied to the side surface of the electronic device using a gas discharger in order to pressurize the filler in a capillary flow direction.

Here, it is preferable that, at the step of applying the filler, the dispenser discharges the filler in at least one method of an Electro Hydro Dynamic method, a pneumatic method, a jet-valve method, a screw pump method, and a syringe pump method.

In addition, it is preferable that, at the step of discharging the gas, the gas discharger discharges the gas in the form of surrounding a periphery of a filler discharge path.

In addition, it is preferable that a location where a pressure of the gas being discharged from the gas discharger is to be concentrated is set to a periphery of an end of the dispenser or to the side surface of the electronic device to which the filler is applied.

In addition, it is preferable that, at the step of discharging the gas, the gas that the gas discharger supplies is controlled to a temperature corresponding to the temperature of the filler while it passes through a gas pipeline disposed inside the dispenser.

In addition, it is preferable that, at the step of discharging the gas, a gas discharge path is set to target an entirety of a filler application path, or to target a partial area of the filler application path.

It is preferable that the partial area is set as an area where penetration speed of the filler is relatively slow.

In addition, it is preferable that the step of applying the filler and the step of discharging the gas are performed simultaneously or sequentially.

In addition, it is preferable to include a step of providing ultrasound waves towards the filler applied to the side surface of the electronic device, after the step of applying the filler.

In addition, it is preferable that the step of providing ultrasound waves is preformed prior to the step of discharging the gas.

In addition, it is preferable to perform a step of setting a filler application path for applying the filler, prior to the step of applying the filler.

In addition, it is preferable that the step of setting the filler application path includes a step of defining a location coordinate of an end of the dispenser, a step of defining a location coordinate of an edge end of a side wall of the electronic device and a step of generating the filler application path according to an aspect ratio of the electronic device.

In addition, it is preferable that, at the step of generating the filler application path, the filler application path is set such that a distance between the end of the dispenser and the edge end of the side wall of the electronic device maintains a preset value.

According to the present disclosure, a method of electronic devices packaging underfill is provided, that can improve the penetration force of the filler for underfilling to minimize void creation and shorten the underfill filling time.

In addition, a method of electronic devices packaging underfill is provided, that uses heated gas to lower the viscosity of the filler being dispensed, thereby further improving the work efficiency of a underfill process.

In addition, a method of electronic devices packaging underfill is provided, where in the case of discharging the filler in the electrohydrodynamic method, along with the electrocapillary effect, low viscosity can be maintained by the heated gas, and thus the capillary force of the filler can be further strengthened and the viscous force can be weakened, making the underfill effective.

### BRIEF DESCRIPTION OF THE DRAWINGS

FIG. 1 is a process flow chart of a method of electronic devices packaging underfill of the present disclosure;

FIG. 2 and FIG. 3 are schematic diagrams of an underfill device used in the method of electronic devices packaging underfill of the present disclosure;

FIG. 4 and FIG. 5 are process diagrams of a filler application path setting step according to the method of electronic devices packaging underfill of the present disclosure;

FIG. 6 and FIG. 7 are process diagrams of a filler application step and a gas discharging step according to the method of electronic devices packaging underfill of the present disclosure;

FIG. 8 is a process diagram of an ultrasound providing step according to the method of electronic devices packaging underfill of the present disclosure; and

FIG. 9 and FIG. 10 are process diagrams showing a state of applying a filler using a plurality of dispensers.

### DETAILED DESCRIPTION

Prior to description, it is to be noted that, in various embodiments, components having the same configuration are typically described in the first embodiment using the same symbols, and in other embodiments, configurations different from the first embodiment are described.

Hereinbelow, the method of electronic devices packaging underfill according to a first embodiment of the present disclosure will be will be described in detail with reference to the drawings attached.

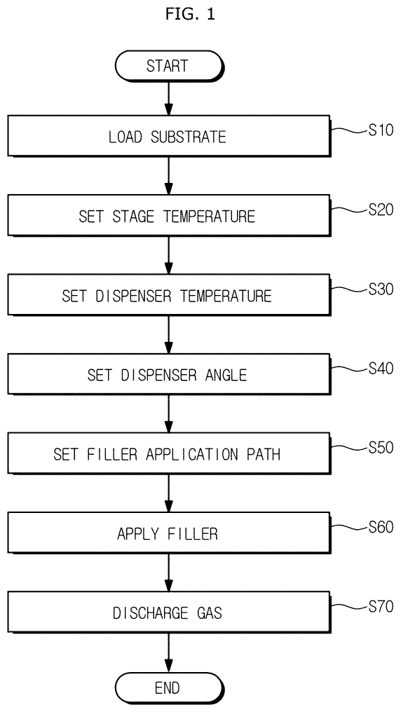

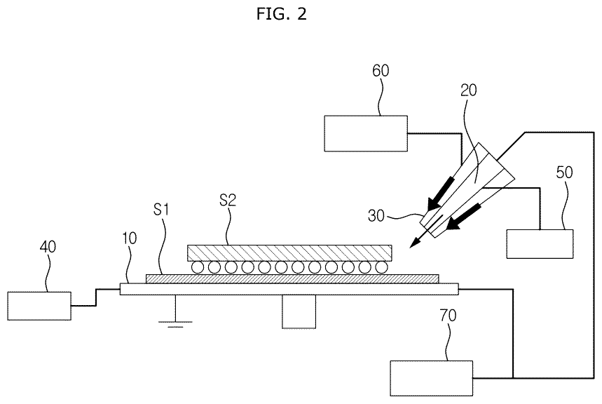

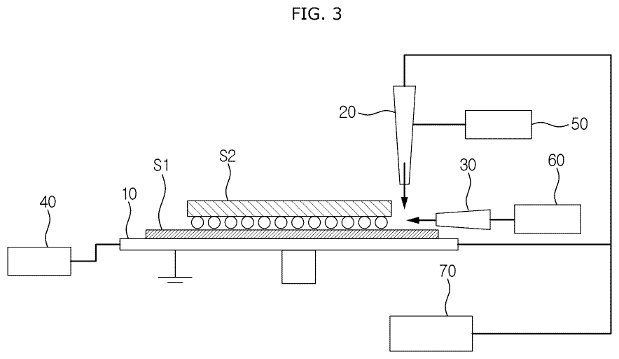

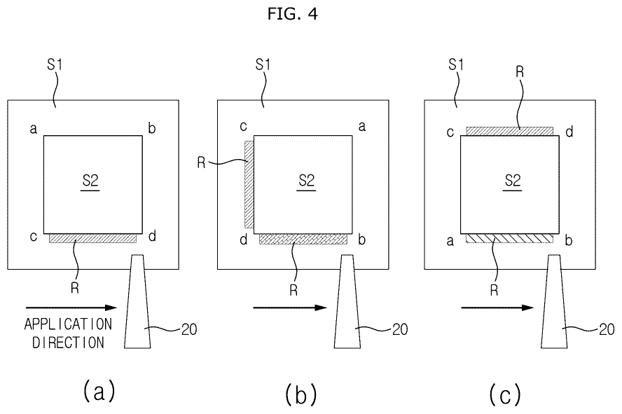

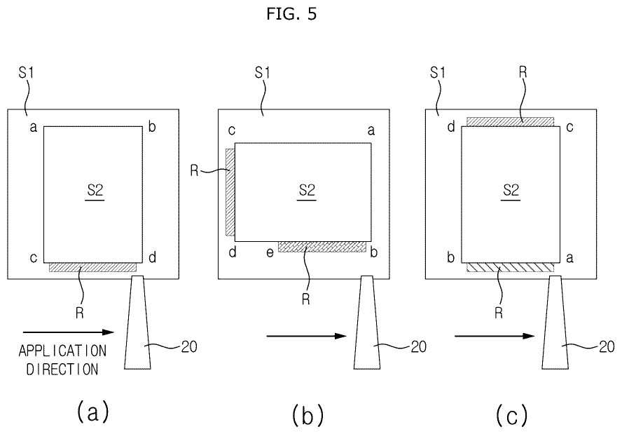

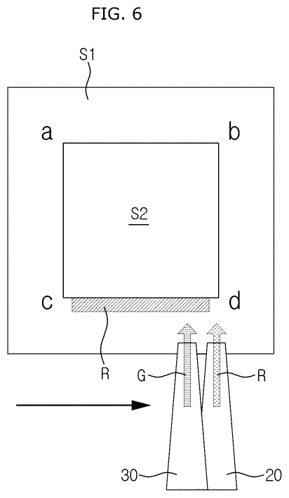

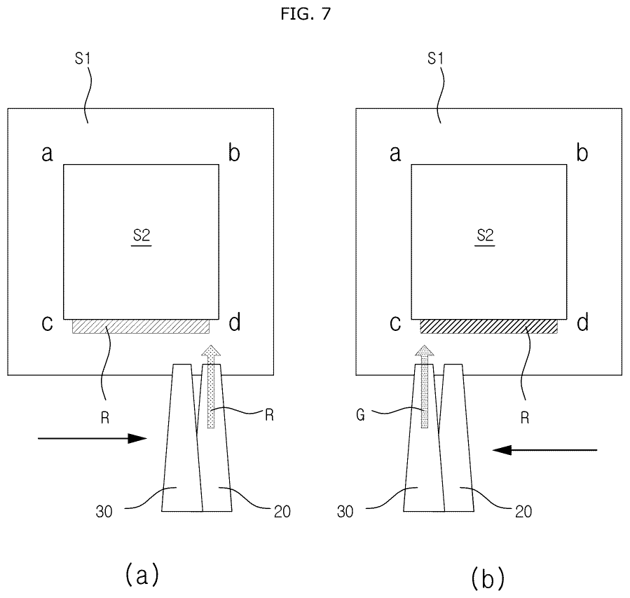

Of the attached drawings, FIG. 1 is a process flow chart of a method of electronic devices packaging underfill of the present disclosure, FIG. 2 and FIG. 3 are schematic diagrams of an underfill device used in the method of electronic devices packaging underfill of the present disclosure, FIG. 4 and FIG. 5 are process diagrams of a filler application path setting step according to the method of electronic devices packaging underfill of the present disclosure, and FIG. 6 and FIG. 7 are process diagrams of a filler application step and a gas discharging step according to the method of electronic devices packaging underfill of the present disclosure.

The method of electronic devices packaging underfill of the present disclosure as shown in the above-mentioned drawings includes a step of loading a substrate (S10), a step of setting a stage temperature (S20), a step of setting a dispenser temperature (S30), a step of setting a dispenser angle (S40), a step of setting a filler application path (S50), a step of applying a filler (S60), and a step of discharging a gas (S70).

At the step of loading the substrate (S10), a subject that requires application of the filler, specifically, the substrate S1 where an electronic device S2 is stacked, is loaded on the stage 10.

At the step of setting the stage temperature (S20), using a first temperature adjuster 40 provided at the stage side 10, the stage 10 is heated or cooled to a preset temperature.

Meanwhile, at the step of loading the substrate (S10) and at the step of setting the stage temperature (S20), prior to loading the substrate S1 on the stage 10, the substrate S1 may wait while the stage 10 is controlled to the set temperature using the first temperature adjuster 40, and when the stage 10 has reached the set temperature, the substrate S1 may be loaded on the stage 10, so that the temperature of the substrate S1 can change to the set temperature. Here, the waiting time may vary depending on the material or thickness of the substrate S1.

At the step of setting the dispenser temperature (S30), using a second temperature adjuster 50 provided at the dispenser 20 side, the dispenser 20 is heated or cooled to a preset temperature.

Here, the first temperature adjuster 40 and the second temperature adjuster 50 may each include a Peltier element capable of cooling control and a heating element capable of heating control.

The setting temperature of the stage 10 and the dispenser 20 may be set in consideration of the surrounding environment of the underfill process, characteristics of the electronic device S2, and physical properties of the filler, etc.

At the step of setting the dispenser angle (S40), the angle of the dispenser 20 may be adjusted to be from 90 degrees to 10 degrees from a flat plate of the stage 10, and through this, the discharge direction of the filler being discharged from the dispenser 20 may be directed towards a gap of an underfill area.

The step of setting the filler application path (S50) includes a step of defining a coordinate by recognizing a location of an end of the dispenser 20 through image processing, a step of defining a coordinate by recognizing a location of an edge end of a side wall of the electronic device S2 through image processing, and a step of generating the filler application path according to an aspect ratio of the electronic device S2 while maintaining the distance between the end of the dispenser 20 and the edge end of the side wall of the electronic device S2 to a preset value.

The distance between the end of the dispenser 20 and the edge end of the side wall of the electronic device S2 may be set to have a distance of 0 to 300 micrometers. If the distance between the dispenser 20 and the electronic device S2 is set to be 0 micrometer or less, there is a concern that the filler being discharged from the dispenser 20 will contaminate an upper surface of the electronic device S2, and If the distance between the dispenser 20 and the electronic device S2 exceeds 300 micrometers, a keep-out zone must be expanded as much as that distance, and thus it is disadvantageous for miniaturization of semiconductor chips.

The filler application path is set such that a void is not generated in the underfill process. This filler application path may be set in the shape of ‘-’, ‘ [symbol] ’, or ‘ [symbol] ’ depending on the aspect ratio of the electronic device S2, or may be set to be applied to each of the two opposing side surfaces of the electronic device S2. In this specification, applying the filler to the side surface of the electronic device S2 may be understood as applying the filler toward the side surface of the electronic device S2 or the outside of the side edge of the electronic device S2. In addition, the filler application path may be set such that the filler is applied multiple times along a set path depending on the size of the electronic device S2, and may be set such that when the filler is applied multiple times, there is a waiting time between an application and a re-application such that the filler applied prior can penetrate sufficiently between the electronic device S2 and the substrate S1.

For example, when two adjacent sides of the electronic device S2 have the same length, the filler application path may be set such that the filler R is applied to any one side (cd) of the electronic device S2 in the shape of ‘-’ as shown in FIG. 4 (a), or such that the filler R is applied to two adjacent sides (cd, bd) of the electronic device S2 in the shape of ‘ [symbol] ’ as shown in FIG. 4 (b), and set such that the filler R is applied to each of the two opposing sides (cd, ab) of the electronic device S2 in the shape of ‘-’ as shown in FIG. 4 (c).

In addition, when the two adjacent sides of the electronic device S2 have different length, the filler application path may be set such that the filler R is applied to a shorter side (cd) of the electronic device S2 in the shape of ‘-’ as shown in FIG. 5 (a), and then such that, following FIG. 5 (a), the filler R is applied to a partial section (eb) of a longer side (bd) that is adjacent to the shorter side (cd), in the shape of ‘ [symbol] ’ as shown in FIG. 5 (b), or such that, following FIG. 5 (a), the filler R is applied to another side (ab) opposing the shorter side (cd) where the filler R is applied, in the shape of ‘-’, as shown in FIG. 5 (c).

The settings of the filler application path described with reference to FIG. 4 and FIG. 5 are mere examples, and may vary in various forms depending on the physical properties of the filler, size and aspect ratio of the electronic device S2, distance between the electronic device S2 and the substrate S1, and arranged state of bumps, etc.

The settings of the filler application path mentioned above was described based on the state of applying the filler using a single dispenser 20, and thus can be appropriately changed depending on the number of dispensers 20.

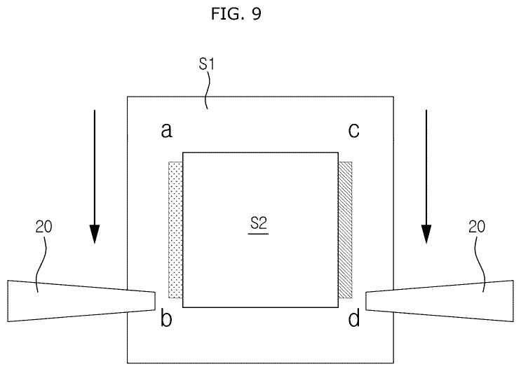

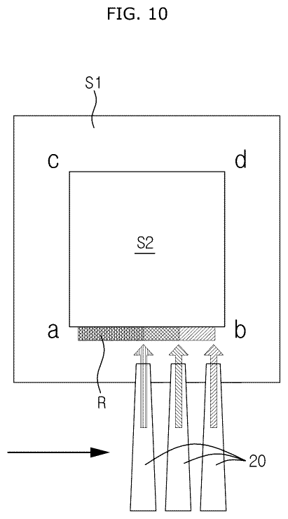

For example, when a plurality of dispensers 20 are prepared, the filler application path may be set such that the filler R is applied simultaneously to two opposing sides (cd, ab) of the electronic device S2 as shown in FIG. 9, or set such that the filler R is applied a plurality of times sequentially to a side surface at one side of the electronic device S2 as shown in FIG. 10.

In addition, in order to generate an appropriate filler application path, it may be set such that in some section of the entire section, the filler is applied by only some selected dispensers 20 of the plurality of dispensers 20.

At the step of applying the filler (S60), in order to perform the underfill process, the liquid underfill filler is applied while moving the dispenser 20 along the filler application path.

The dispenser 20 used at the step of applying the filler (S60) may be configured to discharge the filler in various methods such as a pneumatic (air pressure), Electro Hydro Dynamic (EHD), Jet-valve, Screw-pump, and Syringe-pump, etc.

In the case of the Electro Hydro Dynamic (EHD) method, as in Korean Patent Registration 10-2047025, the filler may be charged and applied between the substrate S1 and the electronic device S2, and then by an electric field, the wettability of the filler may be controlled, thereby further improving the filling efficiency. Particularly, in the case where the filler application path is set to convert direction, the penetration speed of the filler can be improved due to electrowetting by the Electro Hydro Dynamic at the direction conversion point.

In order to discharge the filler using the Electro Hydro Dynamic method, a voltage controller 70 that creates a potential difference between the dispenser 20 and the stage 10 may be further included. For example, the voltage controller 70 may apply a voltage to an electrode disposed on the dispenser 20 side, to generate a potential difference between the electrode and a grounded stage 10. Accordingly, when an electric field is formed between the dispenser 20 and the stage 10, by the electric field, the filler may be discharged towards the stage 10. Since the discharging technology using this Electro Hydro Dynamic method is known through Korean Patent Registration No. 10-2047025, detailed description thereof will be omitted.

Meanwhile, besides the Electro Hydro Dynamic method, the dispenser 20 may use at least one of a pneumatic method, a jet-valve method, or a screw pump method and syringe pump method depending on the characteristics of the filler to be discharged, the characteristics of the electronic device and substrate to be worked on, and the working environment, etc., and the detailed configuration and operating principle of each method are known technology, so detailed description thereof will be omitted.

Meanwhile, at the step of applying the filler (S60), based on the coordinate for the location of the end of the dispenser and the location of the edge end of the side wall of the electronic device S2 recognized through image processing, the location of at least one of the dispenser 20 and the stage 10 may be controlled such that the filler discharged from the dispenser 20 can be applied along the filler application path.

Such location control may be configured in the form of transferring the dispenser 20 in xyz direction, or transferring the stage 10 in xyz direction. Further, such location control may be configured in the form of transferring the stage 10 in z direction and transferring the dispenser 20 in xy direction, or in the form of transferring the stage 10 in xy direction and transferring the dispenser 20 in z direction, and in the form of rotating at least one of the dispenser 20 and stage 10 around z axis.

Meanwhile, the present embodiment was described based on an example that at the step of applying the filler (S60), the filler is applied using one dispenser 20, but it is possible to apply the filler using a plurality of dispensers 20.

For example, as shown in FIG. 9, when a plurality of dispensers 20 are arranged symmetrically on both sides of the center of the electronic device S2 or arranged in parallel with respect to the application direction of the filler, the filler R may be applied simultaneously on two opposing side surfaces (ab, cd) of the electronic device S2.

Further, as shown in FIG. 10, when a plurality of dispensers 20 are arranged in series form with respect to the application direction of the filler (arranged in a row and spaced apart along the application direction), the filler R may be applied sequentially to one side surface at one side of the electronic device S2 using the plurality of dispensers, which may be useful when applying the filler multiple times to the same area.

Meanwhile, it is preferable that the plurality of dispensers 20 shown in FIG. 10 are individually controlled such that they each discharge the filler at an application starting point and finish discharging the filler at an application ending point as they all move in one direction so that the filler can be applied multiple times to the same area.

When configured to discharge the filler using a plurality of dispensers 20 as described above, the speed and productivity of the underfill process can be further improved.

Further, at the step of applying the filler (S60), when necessary, it is possible to control such that the filler is applied by only some selected dispensers 20 of the plurality of dispensers 20.

At the step of discharging the gas (S70), the gas may be discharged towards the filler applied to the side surface of the electronic device S2 using the gas discharger 30, and the discharge direction of the gas is set such that the applied filler can be pressurized in a capillary flow direction.

The gas discharger 30 may be disposed in the form of surrounding the side surface of the dispenser 20 to discharge the gas towards the applied filler as shown in FIG. 2, or may be configured to discharge the gas towards the applied filler from a location separated from the dispenser 20 as shown in FIG. 3. Further, it may be configured to have both the gas discharger 30 shown in FIG. 2 and the gas discharger 30 shown in FIG. 3, and to discharge the gas towards the applied filler through each gas discharger 30.

The supply pressure of the gas being supplied to the gas discharger 30 may be controlled by the flow rate controller 60. Meanwhile, the supply pressure of the gas by the flow rate controller 60 may be changed depending on use environment such as the physical properties of the filler, distance between the substrate S1 and the electronic device S2, and size of the electronic device S2, etc.

When the gas discharger 30 is disposed in the form of surrounding the side surface of the dispenser 20 as shown in FIG. 2, a gas pipeline connecting the flow rate controller 60 and the gas discharger 30 may be disposed to pass through the inside of the dispenser 20. Further, a discharge hole of the gas discharger 30 may be disposed in multiple number in the form of surrounding a periphery of a nozzle of the dispenser 20, or may be made in an annular shape concentric with the nozzle of the dispenser 20.

When the gas pipeline of the gas discharger 30 is disposed inside the dispenser 20, the gas being discharged through the gas discharger 30 may be controlled to have substantially the same temperature as the temperature of the filler being discharged through the dispenser 20. Accordingly, since the periphery of the discharge path of the filler being discharged from the dispenser 20 can be set to the same temperature atmosphere as the filler by the gas being discharged from the gas discharger 30, impact from external environment can be minimized during the process of applying the filler, thereby providing consistent quality.

The location where the pressure of the gas being discharged from the gas discharger 30 is to be concentrated may be set to a periphery of the end of the dispenser 20 or to the side surface of the electronic device S2 to which the filler is applied. When the pressure of the gas is concentrated to the periphery of the end of the dispenser 20, the periphery of the discharge path of the filler is set to the same temperature atmosphere as the filler, and thus the filler can be prevented from being cooled and the diffusivity being reduced in the process where the filler is discharged from the dispenser 20. Further, when the pressure of the gas is set to the side surface of the electronic device S2 where the filler is applied, the pressure at a filling inlet between the electronic device S2 and the substrate S1 becomes higher due to the pressure of the gas, which leads to further improved penetration force of the filler in the underfill process.

Meanwhile, the gas discharger 30, which is separate and independently configured from the dispenser 20, may be set such that the gas discharge direction is in a direction that can pressurize the filler in a capillary flow direction regardless of the angle of the dispenser 20.

In addition, the gas discharger 30 shown in FIG. 3 may be arranged to follow the progressing direction of the dispenser 20. For example, in the case where the dispenser 20 applies the filler while moving to the right direction, the gas discharger 30 may be arranged to the left side of the dispenser 20, whereas in the case where the dispenser 20 applies the filler while moving to the left direction, the gas discharger 30 may be arranged to the right side of the dispenser 20. Not only that, it is also possible to arrange the gas discharger 30 to the left side and to the right side of the dispenser 20, respectively, and configure such that the gas is discharged from the gas discharger 30 arranged in a location following the progressing direction of the dispenser 20.

As described above, in an underfill process, by pressurizing the applied filler in the capillary flow direction using the gas, while the liquid filler is being applied to the side surface of the electronic device S2 or after the liquid filler is applied, the diffusion of the filler in the filling direction will become more active, and thus the creation of voids in the underfill process can be minimized and the filling time of the filler can be further shortened.

The step of applying the filler (S60) and the step of discharging the gas (S70) may be set to be performed simultaneously or sequentially.

Specifically, as shown in FIG. 6, the dispenser 20 may apply the filler R to the side surface of the electronic device S2 while moving along the filler application path set in a parallel direction with one side (cd) of the electronic device S2, and in this process, the gas discharger 30 disposed together with the dispenser 20, may discharge the gas G towards the applied filler R to pressurize the applied filler R in the capillary flow direction (filling direction). That is, the dispenser 20 and the gas discharger 30 may be set to discharge the filler R and the gas G simultaneously while moving along the filler application path together.

In addition, as shown in FIG. 7 (a), the dispenser 20 may apply the filler R to the side surface of the electronic device S2 while moving along the filler application path set in the parallel direction with the one side (cd) of the electronic device S2, and as shown in FIG. 7 (b), the gas discharger 30 may discharge the gas G towards the filler R applied to the side surface of the electronic device S2 while moving in a reverse direction along the filler application path, thereby pressurizing the applied filler R in the capillary flow direction. That is, the dispenser 20 and the gas discharger 30 may discharge the filler R and the gas G sequentially while moving alone or together along the filler application path.

The filler application path as described above may be divided into two or more unit sections, and so it is also possible to configure such that the filler R and the gas G are discharged simultaneously or sequentially while moving the dispenser 20 and the gas discharger 30 per each divided unit section.

Further, by discharging the gas G while moving the gas discharger 30 along the filler application path after the application of the filler is completed, to additionally pressurize the previously applied filler R in the capillary flow direction, penetration force of the filler R may be further promoted.

Meanwhile, the gas discharge path by the gas discharger 30 at the step of discharging the gas (S70) may be set to target the entirety of the filler application path, or may be set to target a partial area of the filler application path, and it may also be set to discharge the gas additionally to the partial area after discharging the gas to the entirety of the filler application path. Depending on the location of the filler application, the penetration speed of the filler may vary. For example, the penetration speed of the filler in the longer side and the shorter side may vary, and even in a single side, the penetration speed may vary between the both edge areas of the side and the middle area of the side. Therefore, the penetration speed of the area where the penetration speed is relatively slow can be increased by additionally discharging the gas. Here, it is preferable that the partial area is set as an area where the penetration speed of the filler is relatively slow.

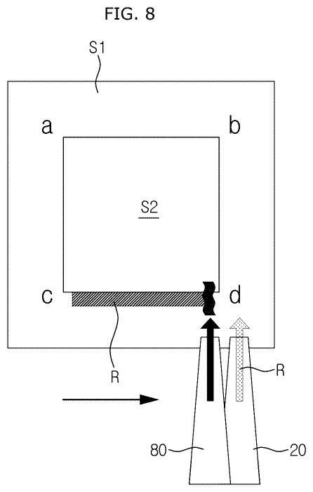

Of the attached drawings, FIG. 8 is a process diagram of an ultrasound providing step according to the method of electronic devices packaging underfill of the present disclosure.

The method of electronic devices packaging underfill according to the present embodiment may further include a step of providing ultrasound (S80) towards the filler applied to the side surface of the electronic device.

The step of providing ultrasound (S80) is performed by performing the step of applying the filler (S60) as shown in FIG. 8 and then propagating ultrasound waves towards the applied filler R using an ultrasound generator 80, thereby vibrating the filler R. In a state where the filler R is vibrated by ultrasound waves, the viscosity of the filler R is further lowered, so the penetration speed of the filler R in the capillary flow direction between the electronic device S2 and the substrate S1 can be increased.

Not only that, if the step of providing ultrasound waves (S80) is performed between the step of applying the filler (S60) and the step of discharging the gas (S70), the discharge pressure of the gas provided at the step of discharging the gas (S70) acts on the filler R whose viscosity is lowered by the vibration of the ultrasound, and thus the flow of the filler in the capillary flow direction can be further promoted.

The scope of the present disclosure is not limited to the above-described embodiments, but may be implemented in various forms of embodiments within the scope of the appended claims. It is deemed to be within the scope of the claims of the present disclosure to the extent that anyone skilled in the art can make modifications without departing from the gist of the present disclosure as claimed in the claims.

### REFERENCE NUMERALS

S1: SUBSTRATE, S2: ELECTRONIC DEVICE, 10: STAGE, 20: DISPENSER, 30: GAS DISCHARGER, 40: FIRST TEMPERATURE ADJUSTER, 50: SECOND TEMPERATURE ADJUSTER, 60: FLOW RATE CONTROLLER, 70: VOLTAGE CONTROLLER, 80: ULTRASOUND GENERATOR, R: FILLER, G: GAS

What is claimed is:

1. A method of electronic devices packaging underfill, the method comprising:
loading a substrate, where an electronic device is stacked, on a stage;
transferring heat so that the substrate maintains a constant temperature;
transferring heat so that a dispenser for discharging a liquid filler maintains a constant temperature;
applying the filler for underfilling to a side surface of the electronic device using the dispenser; and
discharging a gas towards the filler applied to the side surface of the electronic device using a gas discharger in order to pressurize the filler in a capillary flow direction.

2. The method of electronic devices packaging underfill, according to claim 1,
wherein while applying the filler, the dispenser discharges the filler in at least one method of an electro hydro dynamic method, a pneumatic method, a jet-valve method, a screw pump method, and a syringe pump method.

3. The method of electronic devices packaging underfill, according to claim 1,
wherein while discharging the gas, the gas discharger discharges the gas in a form of surrounding a periphery of a filler discharge path.

4. The method of electronic devices packaging underfill, according to claim 3,
wherein a location where a pressure of the gas being discharged from the gas discharger is to be concentrated is set to a periphery of an end of the dispenser or to the side surface of the electronic device to which the filler is applied.

5. The method of electronic devices packaging underfill, according to claim 3,
wherein while discharging the gas, the gas that the gas discharger supplies is controlled to a temperature corresponding to the temperature of the filler while it passes through a gas pipeline disposed inside the dispenser.

6. The method of electronic devices packaging underfill, according to claim 1,
wherein while discharging the gas, a gas discharge path is set to target an entirety of a filler application path, or to target a partial area of the filler application path.

7. The method of electronic devices packaging underfill, according to claim 6,
wherein the partial area is set as an area where penetration speed of the filler is relatively slow.

8. The method of electronic devices packaging underfill, according to claim 1,
wherein while applying the filler and the step of discharging the gas are performed simultaneously or sequentially.

9. The method of electronic devices packaging underfill, according to claim 1,
further comprising after applying the filler, providing ultrasound waves towards the filler applied to the side surface of the electronic device.

10. The method of electronic devices packaging underfill, according to claim 9,
wherein providing ultrasound waves is preformed prior to discharging the gas.

11. The method of electronic devices packaging underfill, according to claim 1,
further comprising prior to applying the filler, setting a filler application path for applying the filler.

12. The method of electronic devices packaging underfill, according to claim 11,
wherein setting the filler application path comprises defining a location coordinate of an end of the dispenser, defining a location coordinate of an edge end of a side wall of the electronic device and generating the filler application path according to an aspect ratio of the electronic device.

13. The method of electronic devices packaging underfill, according to claim 12,
wherein, while generating the filler application path, the filler application path is set such that a distance between the end of the dispenser and the edge end of the side wall of the electronic device maintains a preset value.

14. The method of electronic devices packaging underfill, according to claim 1,
wherein, while applying the filler, the filler is set such that the filler is applied to the side surface of the electronic device simultaneously or sequentially using a plurality of dispensers disposed in different locations from one another.
